(19) United States
(12) Patent Application Publication
(10) Pub. No.: US 2011/0172939 A1
(43) Pub. Date: Jul. 14, 2011

(54) System and Method to Determine an Internal Resistance and State of Charge, State of Health, or Energy Level of a Rechargeable Battery

(76) Inventors: Sandip Uprety, Tucson, AZ (US); Edward McKernan, Oro Valley, AZ (US)

(21) Appl. No.: 12/684,814

(22) Filed: Jan. 8, 2010

(51) Int. Cl. G01R 31/36

(52) U.S. Cl. 702/63

(57) ABSTRACT

A battery monitoring system includes a current, voltage, and temperature sensor. The system includes a processor in communication with each of the current, voltage, and temperature sensor that is configured to read a first bulk current of the at least one of a battery and a battery cell at a first time using the current sensor, and, when the first bulk current is less than a first threshold, read a second bulk current of the at least one of a battery and a battery cell at a second time using the current sensor. When the second bulk current has a value between a second threshold and a third threshold and the difference between the first time and the second time is less than a pre-determined delay threshold, the processor is configured to use the first and second bulk current values to determine an internal resistance of the battery or cell.

### FIELD

Various implementations of the present invention, and combinations thereof, are related to battery monitoring systems and, more particularly, to a monitoring system and method for determining an internal resistance, state of charge (SOC), state of health (SOH) and battery energy level (BEL) of a rechargeable cell or battery pack.

### CROSS-REFERENCE TO RELATED APPLICATIONS

N/A.

### BACKGROUND

A battery is an electronic component that stores electrical energy. Many batteries operate by storing electrical energy in the form of chemical energy using several voltaic cells connected in series by a conductive electrolyte. One half-cell includes an anode and the other half-cell includes a cathode. As the battery operates, a reduction-oxidation (redox) process occurs, causing cations to be reduced at the cathode, while anions are oxidized (removal of electrons) at the anode. During the redox process an electrical potential is created across the terminals of the battery.

Some batteries are configured to be re-charged. During the re-charging process, an electrical potential is applied across the terminals of the battery and the redox process described above is reversed—active material within the battery is oxidized, producing electrons, while the negative material in the battery is reduced, consuming electrons. After charging the battery, a load can be connected across the battery terminals. The original redox process occurs and the load is powered by the chemical energy stored within the battery.

Battery monitoring systems may be used in conjunction with existing batteries and battery cells to determine their status and health. The battery monitoring systems can measure the overall health of the battery and provide estimates of the energy reserves of a particular battery or cell. In some cases, the monitoring system will modify an operation of the battery based upon the data detected by the monitoring system. For example, some existing battery monitoring systems can be configured to adjust an environment or load of a particular battery of cell, for example.

In some cases, battery monitoring systems attempt to determine a state of charge (SOC), state of health (SOH) and battery energy level (BEL) of a rechargeable cell or battery pack. Generally, the SOC of a battery or cell indicates the amount of charge present in a particular battery or cell. The SOH of a battery or cell indicates the aging of the battery or cell and its functionality compared to a new one, and the BEL indicates an amount of energy that is available for supply from the battery or cell at a particular moment.

Many existing mechanisms for monitoring batteries and cells require that the operation of a battery or cell be halted to allow the battery to be subjected to a series of tests to evaluate the battery or cell. In many cases, these tests require that the battery or cell be removed from the system in which the battery or cell is installed and connected to an appropriate testing load before the evaluation tests can be performed. Also, because the characteristics of a battery or cell can vary based upon ambient temperature, many of the existing testing algorithms require that the battery or cell be tested at a pre-determined temperature at which the battery or cell has known characteristics. These restrictions on existing battery testing methods and algorithms can be time consuming and expensive and limit the effectiveness of existing battery monitoring systems.

### SUMMARY

In one embodiment, the present invention is a battery monitoring system. The battery monitoring system includes a current sensor configured to measure a bulk current of at least one of a battery and a battery cell, a voltage sensor configured to measure a terminal voltage of the at least one of a battery and a battery cell, and a temperature sensor configured to measure a temperature of the at least one of a battery and a battery cell. The system includes a processor in communication with each of the current sensor, voltage sensor, and temperature sensor. The processor is configured to read a first bulk current of the at least one of a battery and a battery cell at a first time using the current sensor, and, when the first bulk current is less than a first threshold, read a second bulk current of the at least one of a battery and a battery cell at a second time using the current sensor. When the second bulk current has a value between a second threshold and a third threshold and the difference between the first time and the second time is less than a pre-determined delay threshold, the processor is configured to use the first and second bulk current values to determine an internal resistance of the battery or cell.

In another embodiment, the present invention is a battery monitoring system comprising a memory for storing data, and a processor for communicating with each of a current sensor, voltage sensor, and temperature sensor. The processor is configured to record load current values and terminal voltage values of at least one of a battery and a cell in the memory, and detect a step change in load current of the at least one of a battery and a cell. The step change begins at a first time and ends at a second time. The processor is configured to use a first load current value and a first terminal voltage value of the at least one of a battery and a cell detected at the first time, and a second load current value and a second terminal voltage value of the at least one of a battery and a cell detected at the second time to determine an internal resistance of the at least one of a battery and cell.

In another embodiment, the present invention is a battery monitoring system comprising a processor, a computer readable medium, a current sensor, a temperature sensor, a voltage sensor, and computer readable program code encoded in the computer readable medium to monitor the status of at least one of a battery and a battery cell. The computer readable program code comprises a series of computer readable program steps to effect reading a first bulk current of the at least one of a battery and a battery cell at a first time. When the first bulk current is less than a first threshold, the computer readable program code comprises a series of computer readable program steps to effect reading a second bulk current of the at least one of a battery and a battery cell at a second time. When the second bulk current has a value between a second threshold and a third threshold and the difference between the first time and the second time is less than a delay threshold, computer readable program code comprises a series of computer readable program steps to effect using the first and second bulk current values to determine an internal resistance of the battery or cell.

In another embodiment, the present invention is a battery monitoring system comprising a processor, a computer readable medium, a current sensor, a temperature sensor, a voltage sensor, and computer readable program code encoded in the computer readable medium to monitor the status of at least one of a battery and a battery cell. The computer readable program code comprises a series of computer readable program steps to effect recording load current values and terminal voltage values of at least one of a battery or cell in the memory, and detecting a step change in load current of the at least one of a battery and a cell. The step change begins at a first time and ends at a second time. The computer readable program code comprises a series of computer readable program steps to effect using a first load current value and a first terminal voltage value detected at the first time, and a second load current value and a second terminal voltage value detected at the second time to determine an internal resistance of the at least one of a battery and cell.

### BRIEF DESCRIPTION OF THE DRAWINGS

Implementations will become more apparent from the detailed description set forth below when taken in conjunction with the drawings, in which like elements bear like reference numerals.

FIG. 1 is a flowchart showing an example method for determining an internal resistance of a battery or cell in accordance with the present disclosure, the internal resistance may then be compensated and used to determine a state of health (SOH) of the battery or cell;

FIG. 2 is an illustration of the measurements that may be captured in steps 106 and 110 of FIG. 1;

FIG. 3 is a graph showing a normalized curve of the temperature response of the internal resistance for a battery or cell;

FIG. 4 is a graph showing a normalized curve of the internal resistance of a battery or cell for a given state of charge (SOC);

FIG. 5 is a graph showing a curve of the SOC of a new battery or cell for a given open cell voltage (OCV);

FIG. 6 is a graph showing a normalized curve of the measured internal resistance of a battery or cell given a step change in measured bulk current;

FIG. 7 is a graph showing the SOH of a battery or cell for a given ratio of measured internal resistance (R_int_average) to the internal resistance of a new battery or cell;

FIG. 8 is a flowchart showing an example method for determining an SOC of a battery or cell;

FIG. 9 is a flowchart showing an example method for determining a battery energy level (BEL) of a battery or cell;

FIG. 10 is a graph showing a lookup curve for a battery energy level (BEL) temperature compensation coefficient with respect to temperature;

FIG. 11 is a graph showing a lookup curve for a normalized BEL of a battery or cell with respect to discharge rate normalized around a value of 1C;

FIG. 12 is an illustration of some of the functional components in an exemplary implementation of the present system; and

FIG. 13 is a schematic showing an example interconnection of various components of the system illustrated in FIG. 12.

### DETAILED DESCRIPTION

The present invention is described in preferred embodiments in the following description with reference to the Figures, in which like numbers represent the same or similar elements. Reference throughout this specification to “one embodiment,” “an embodiment,” or similar language means that a particular feature, structure, or characteristic described in connection with the embodiment is included in at least one embodiment of the present invention. Thus, appearances of the phrases “in one embodiment,” “in an embodiment,” and similar language throughout this specification may, but do not necessarily, all refer to the same embodiment.

The described features, structures, or characteristics of the invention may be combined in any suitable manner in one or more embodiments. In the following description, numerous specific details are recited to provide a thorough understanding of embodiments of the invention. One skilled in the relevant art will recognize, however, that the invention may be practiced without one or more of the specific details, or with other methods, components, materials, and so forth. In other instances, well-known structures, materials, or operations are not shown or described in detail to avoid obscuring aspects of the invention.

Existing battery monitoring systems generally require that the operation of a battery or cell be halted to allow that the battery or cell be subjected to a series of tests to evaluate the state of charge (SOC), state of health (SOH) and battery energy level (BEL) of the battery or cell. In many cases, this requires that the battery or cell be removed from the system in which the battery or cell is installed, and connected to an appropriate testing load before the evaluation tests can be performed. Similarly, because the characteristics of a battery or cell can vary based upon ambient temperature, many existing testing algorithms require that the battery or cell be tested at a pre-determined temperature at which the battery or cell has known characteristics. These restrictions on existing battery testing methods and algorithms can be time consuming and expensive.

The present system provides a battery monitoring system and, more particularly, a monitoring system and method for determining a SOC, SOH and BEL of a rechargeable cell or battery pack. The present system and method may be implemented using measurement data for a cell voltage, cell current, and cell temperature, and may include a microcontroller for implementation. The system and method analyzes the dynamic operation a battery or cell to calculate the battery or cell's internal resistance and does not require the application of any additional or substitute external loads.

In many systems that use rechargeable batteries or cells, essential parameters like cell voltage, current and temperature are monitored continuously by the charging systems themselves. The monitoring may be done by conventional voltage, current and temperature sensors that make the associated data available for use by other system components. As such, the measurements and data values used during implementation of the present system and method may be made available by safety systems implemented in available charging systems. For example, in many charging systems, safety features like over-voltage, over-current and over-temperature protection are provided. As a result, the cell voltage, current and temperatures of the battery or cell are continuously monitored in the majority of available charging circuits. Consequently, in one implementation, the present system and method uses existing voltage, current and temperature measurements provided by existing charging systems and may, therefore, be used in conjunction with existing charging systems.

The present system and method may be implemented to monitor a battery or cell system continuously. This operation is in contrast to existing monitoring systems that may require removal of the battery or cell and that any testing be performed at a specific temperature and state of charge. Existing test algorithms cannot compensate for changes in SOC and SOH with respect to a change in temperature, discharge current and the SOC. In contrast, the present system and method may be configured to compensate for the changes in voltage, internal resistance, and energy level of the battery, with respect to temperature, state of charge, and discharge rate. As a result, the present system and method may evaluate the state of a battery or cell at any time.

Furthermore, in existing monitoring systems, the normal operation of the battery or cell must be halted to implement the existing monitoring and testing algorithms. In contrast, the present system evaluates the dynamic real-time operation of the battery or cell. The system detects step changes in load current when the battery is in normal operation in real time. If the system detects a step change in load current, the system uses the initial and final terminal voltages and bulk currents through the battery or cell to calculate the battery or cell's internal resistance. The internal resistance may then be used in combination with other additional information to determine one or more operational characteristics of the battery or cell such as SOH, SOC and BEL or the battery or cell.

Accordingly, the present system does not require that the battery or cell be subject to a pre-determined testing algorithm involving certain loads, current discharge, and temperatures. Instead, the operation of the battery or cell is continuously monitored as it operates within a particular piece of equipment. As the equipment operates, the battery or cell will be subject to varying loads and, consequently, have varying output characteristics. Eventually, through normal operation of the system, the battery or cell will be subjected to a combination of loads giving rising to an operation of the battery or cell that may be used to characterize the SOC, SOH, and BEL of the battery or cell. As a result, the present system and method may operate continuously without affecting normal battery operation and may continuously monitor the SOC, SOH and BEL of the battery or cell.

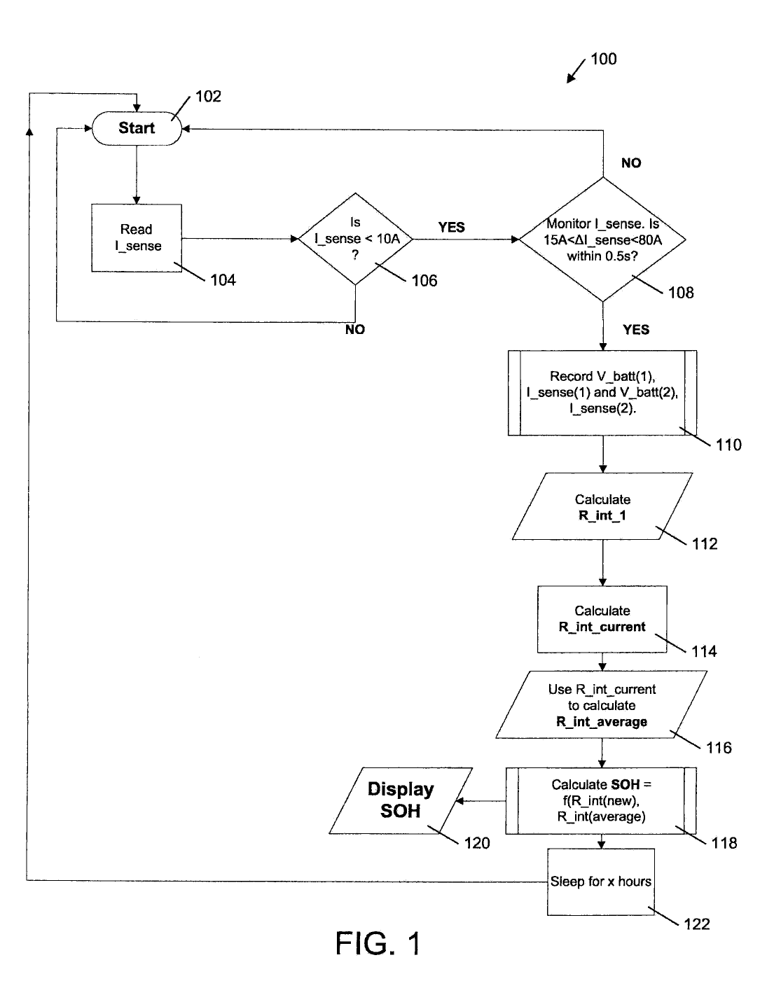

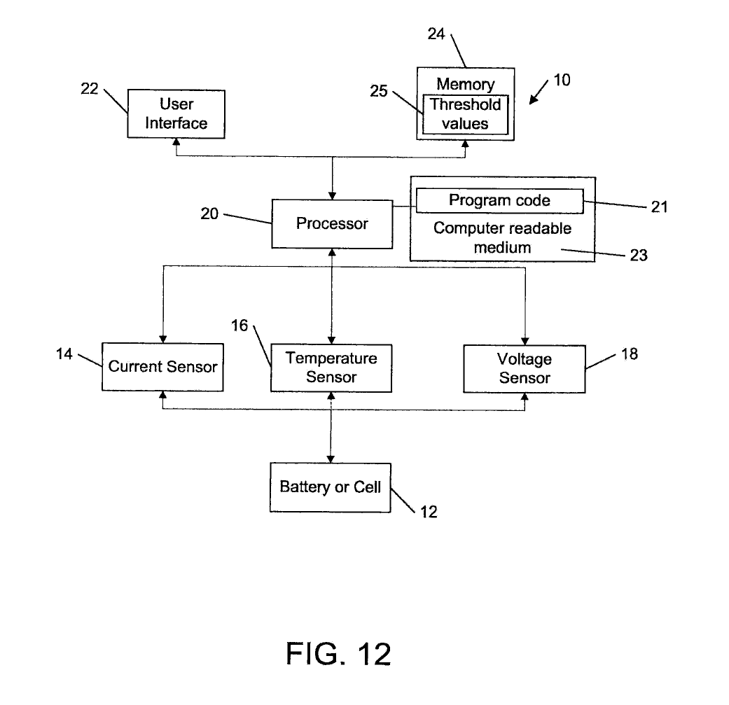

FIG. 1 is a flowchart showing an example method 100 for determining an internal resistance of a battery or cell in accordance with the present disclosure. The internal resistance may then be used to determine a SOH of the battery or cell. Method 100 may be implemented by system 10 illustrated in FIG. 12 and described below. As illustrated, method 100 includes some particular values that may be used in the depicted method. It should be appreciated, however, that in different applications using different batteries or cells, different loads, and having different performance requirements, other values may be substituted and used in the present system.

The method starts with step 102. In step 104, system 10 first reads the bulk discharge current of the battery or cell (I_sense) using a current sensor, such as those provided in existing battery charging safety systems and illustrated in FIG. 12. After retrieving a value of I_sense, the system determines whether I_sense is less than a certain threshold in step 106. The threshold is pre-determined and may be retrieved from a system memory (e.g., threshold memory 25 of memory 24 as illustrated in FIG. 12), for example. In one implementation of the present system, the I_sense threshold is set to a numerical value approximately equal to one third of the amp-hour capacity of the battery or cell being monitored. For example, as shown in FIG. 1, the threshold may be set to 10 Amps (A) for a battery or cell having a 30 Amp-Hour capacity. If I_sense is greater than the threshold, system 10 returns to step 102 to begin the process over again. Accordingly, the present system is “triggered” by I_sense falling below a pre-determined threshold.

If I_sense was less than the threshold in step 106, at that time system 10 is triggered and detects and stores a bulk current value and terminal voltage value for the battery or cell (e.g., I_sense(1) and V_batt(1)). After being triggered, in step 108, system 10 continues to monitor I_sense to detect whether the value of I_sense transitions to a value between two predetermined threshold values within a particular time frame. The additional threshold values may be stored in, for example, threshold memory 25 of memory 24 as illustrated in FIG. 12.

In the present example, the lower threshold value of step 108 may be set to a value sufficiently greater than the threshold of step 106 to avoid measurement errors due to system noise. For example, the lower threshold value in step 108 may be set to a numerical value equal to one-half the amp-hour capacity of the battery or cell being tested (e.g., the lower threshold is set to 15 A for a 30 Amp-Hour battery or cell) or the threshold of step 104 plus an appropriate offset (e.g., the threshold of step 104 plus 50% of the threshold of step 104).

The upper threshold of step 108 is set to a sufficiently low value to avoid transient voltage dip within the battery or cell, such as that resulting from Coupe de Fouet (CDF). In one implementation, the upper threshold may be set to a numerical value equal to three times the amp-hour capacity of the battery or cell being tested (e.g., the upper threshold may be set to 90 A for a 30 Amp-Hour battery or cell). With regards to step 108, the time frame can be adjusted based upon inherent delays within the circuitry of system 10 and other operational elements of the battery monitoring system or the battery or cell itself. In some system implementations one or more of the second and third threshold are not defined. In that case, it is only necessary in step 108 that the single defined threshold be met.

In the specific example illustrated in FIG. 1, the system determines whether I_sense, within 0.5 s of the reading in step 106, has a value between two thresholds, e.g., 15 A and 80 A. If not, the system returns to step 102. If, however, the criteria is satisfied, the system has detected a step-change in current and records several measurements from the battery or cell to system 10 memory in step 110. With reference to FIG. 1, the system records a first voltage and current of the battery or cell (i.e., V_batt(1) and I_sense(1)) at a first time (e.g., when step 106 was executed) and a second voltage and current (i.e., V_batt(2) and I_sense(2)) at a second time (e.g., when the criteria of step 108 were satisfied).

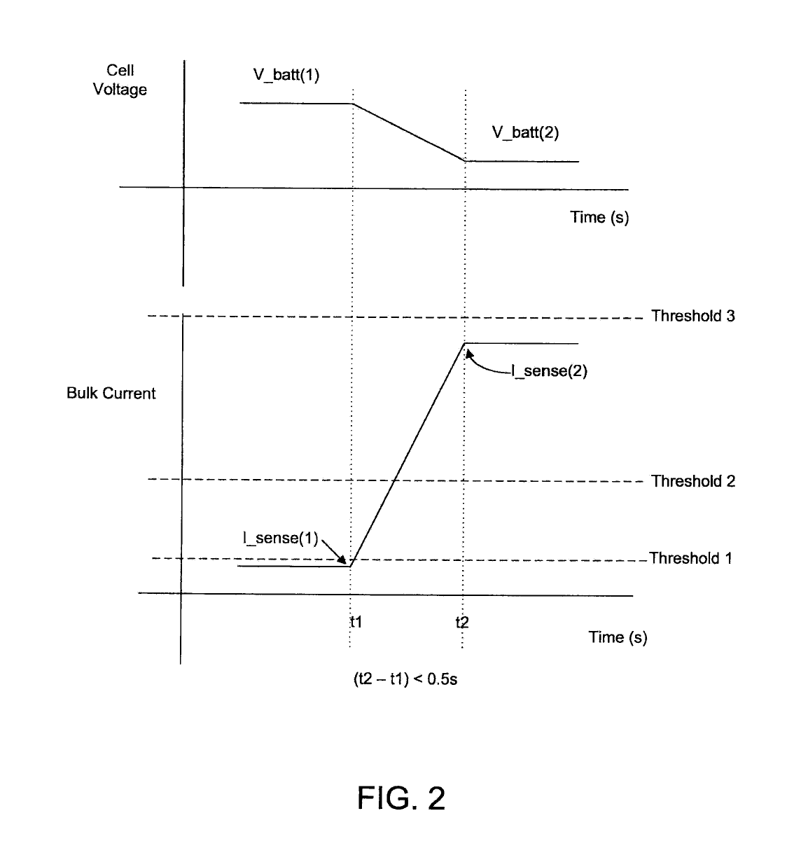

For further reference, FIG. 2 is an illustration of the measurements that may be captured in steps 106 and 110 of FIG. 1. With reference to FIG. 2, I_sense(1) falls below Threshold 1 (as required by step 106 of FIG. 1) and I_sense(2) falls above Threshold 2 and below Threshold 3 (as required by step 108 of FIG. 1). Furthermore, the time interval between the readings of I_sense(1) and V_batt(1), and the readings of I_sense(2) and V_batt(2) is less than the predetermined duration (e.g., 0.5 s).

Returning to FIG. 1, using the values of I_sense(1), V_batt(1), I_sense(2), and V_batt(2), the system calculates an internal resistance (R_Int_{—}1) of the battery or cell in step 112. In one implementation, the system solves equation (1) to determine a value of R_int_{—}1.

$$R\_int \_ 1 = \vert \frac{V\_batt ( 2 ) - V\_batt ( 1 )}{I\_sense ( 2 ) - I\_sense ( 1 )} \vert \qquad Equation ( 1 )$$

After determining R_int_{—}1, the system calculates R_int_current by compensating the value of R_int_{—}1 for various characteristics of the battery or cell in step 114. For example, compensation may be performed based upon a temperature of the battery or cell (the temperature may have been detected and stored in system 10 memory as part of steps 106, 108, or 110, for example), SOC and discharge rate data. As such, the system takes into consideration the variance in internal resistance of the battery or cell due to changes in temperature, SOC, and the discharge rate. Each of the temperature, SOC and discharge rate compensations, however, is optional and in various implementations of the present system, one or more of the compensations may not be performed.

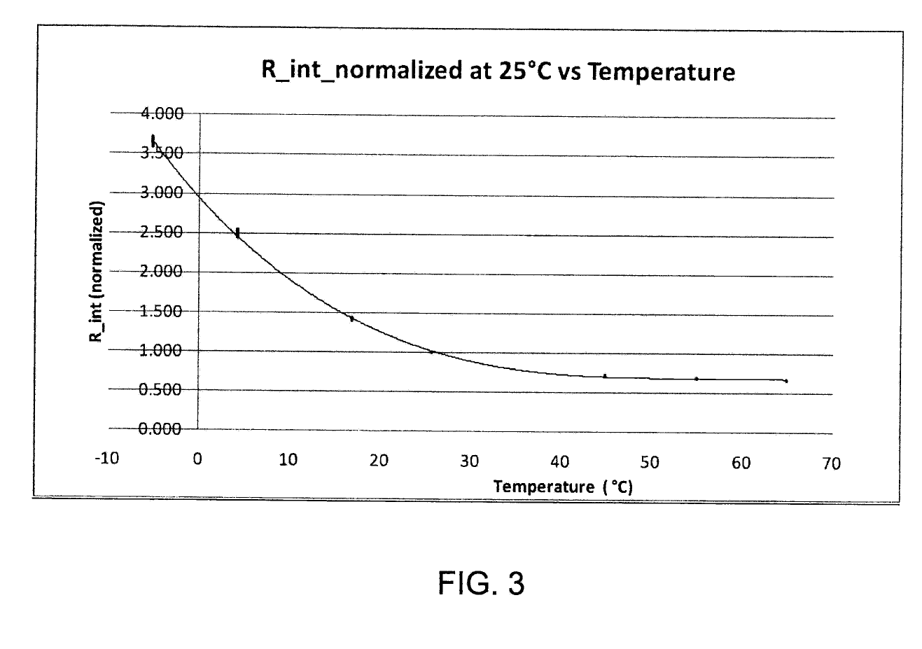

To perform temperature compensation, the system may access pre-determined data stored in system 10 memory (see, for example, FIG. 12) that describes the temperature response of the internal resistance of a new battery or cell. The data can then be used to compensate the measured internal resistance of the battery or cell being tested. The temperature compensation data may include experimental data that describes the temperature response of the internal resistance for a new battery or cell (R_int_new) of the same type as that being tested. For example, FIG. 3 is a graph showing a normalized curve of the temperature response of R_int_new for a new battery or cell. The graph is normalized around 25 degrees Celsius and shows how, as temperature decreases, the internal resistance of the new battery or cell increases. The data illustrated in FIG. 3 (and any other graphs presented in this disclosure) may be stored in a memory of system 10 and used as a reference table by system 10. For example, the data may be discretized and stored in a table, database, multi-dimensional array, or other data structure for use by system 10. System 10 can then access the stored data to determine an appropriate R_int compensation factor for the battery or cell being tested based upon temperature. For example, with reference to FIG. 3, if the present temperature of the battery or cell being tested is 5 degrees Celsius, the system divides R_int_{—}1 by a value of 2.5 to determine the temperature compensated value for R_int_{—}1, which represents the internal resistance at room temperature.

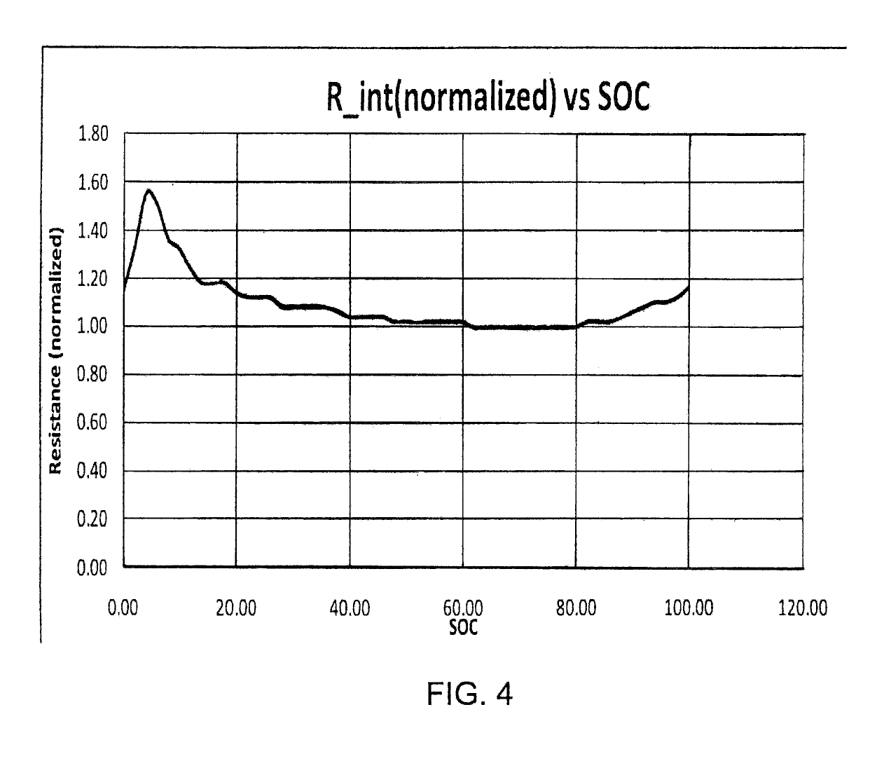

To perform SOC compensation for the battery or cell, the system may use experimental data describing the SOC response of R_int for a new battery or cell to determine an appropriate compensation factor for the battery or cell being tested. The data may be captured experimentally and, as in the case of temperature compensation data, may be discretized and stored in a memory of system 10. For example, FIG. 4 is a graph showing a normalized curve of R_int for a new battery or cell in response to the SOC of the battery or cell. The graph data may be stored in a memory of system 10 and used by system 10 to perform compensation. After accessing the data, system 10 can determine an appropriate factor to compensate the internal resistance of the battery or cell due to the battery or cell's SOC conditions.

To perform SOC compensation, the SOC of the battery or cell must first be calculated. In one example, the SOC of the battery or cell may be determined by first calculating an open cell voltage (OCV) of the battery or cell using the equation OCV=V_batt+I_sense*R_int. The values of V_batt and I_sense have been previously captured in step 110 of method 100. If a prior value of R_int has been determined for the battery or cell in accordance with the present disclosure, that value may be used in the equation to determine OCV. If, however, prior values of R_int are unavailable, the SOC compensation step may be omitted from the present method. Alternatively, if prior values of R_int are unavailable, the equation for determining the value of OCV may be modified. For example, if the battery or cell is relatively new, it will have a relatively low internal resistance. Accordingly, for a new battery, if the OCV is calculated at a relatively low current, the value of the multiple of R_int and I_sense may be assumed to go to 0. As such, if the value of V_batt is set equal to V_batt(1) measured in step 106 of FIG. 1, which was measured at a relatively low current, the value of R_Int multiplied by I_sense goes to 0. In that case, the equation for determining OCV is simplified to OCV=V_batt (in this case, V_batt(1)) and no value of R_int is necessary to determine the OCV of the battery or cell.

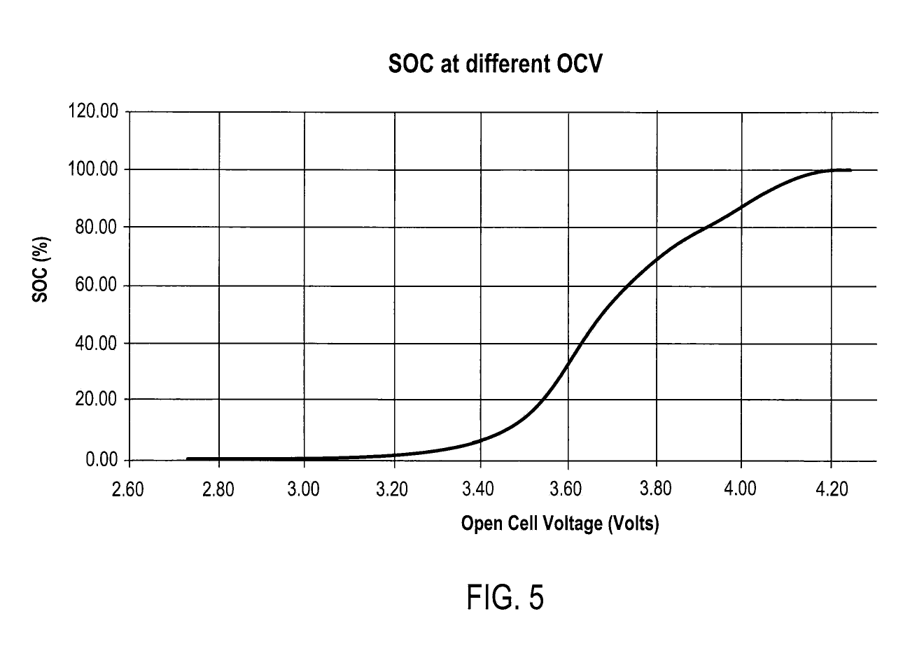

After determining the OCV for the battery or cell being tested using one of the above methods, the experimental data illustrated in FIG. 5 may be used to map the OCV to an SOC for the battery or cell. FIG. 5 is a graph showing a curve of the SOC response of a new battery or cell for a given OCV. The data illustrated in FIG. 5 may be captured experimentally and may be discretized and stored within a memory of system 10. After determining an SOC for the battery or cell, system 10 looks to the experimental data in FIG. 4 to determine an appropriate internal resistance compensation factor based upon the SOC. After determining the factor, the system divides the temperature-adjusted R_int value by the SOC compensation factor.

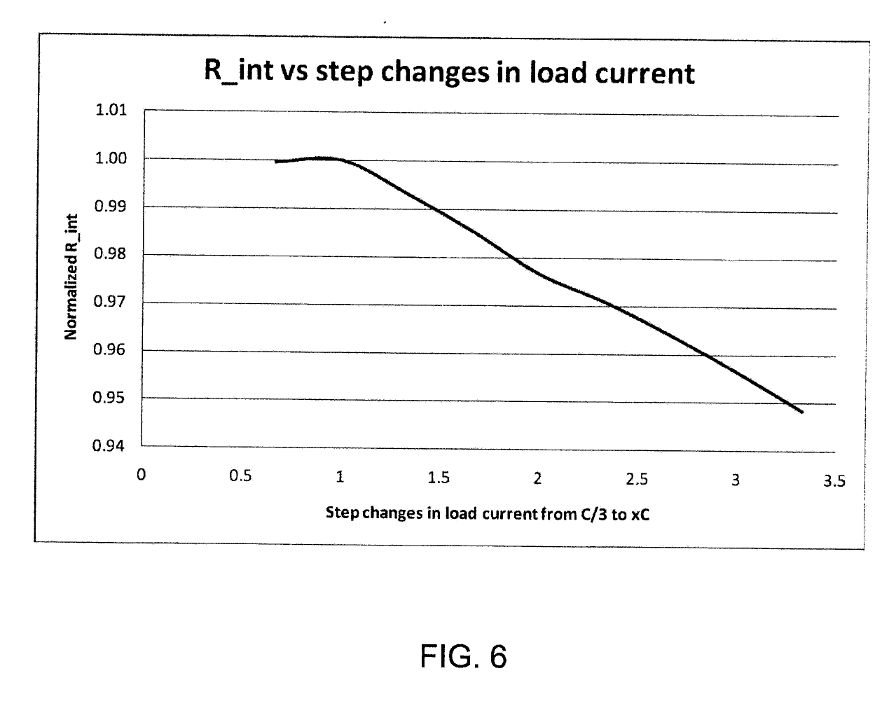

Discharge rate compensation may also be performed to compensate for variance in the internal resistance of the battery or cell due to the step change in the load current detected in step 108. To perform discharge rate compensation, the difference between I_sense(2) and I_sense(1) is first determined. After determining the difference between I_sense(2) and I_sense(1), the experimental data illustrated in FIG. 6 is used to determine a discharge rate compensation factor to be divided by R_int_{—}1. FIG. 6 is a graph showing a normalized curve of the measured R_int given a step change in bulk current of a new battery or cell. Again, the experimental data illustrated in FIG. 6 may be discretized and stored in a table or other data structure accessible to system 10. As seen in FIG. 6, as the discharge rate increases (and, consequently, the magnitude of the difference between I_sense(2) and I_sense(1) increases) the measured value of R_int decreases. Accordingly, discharge rate compensation may be performed to account for that variance in the measured value of R_int.

In optional step 116, multiple prior calculated values of R_int_current are stored in a memory of system 10 and may be averaged together. In this example, the last 100 values of R_int_current are averaged together. The averaging step may prevent occasional data anomalies from causing wildly varying values of R_int_current to be calculated.

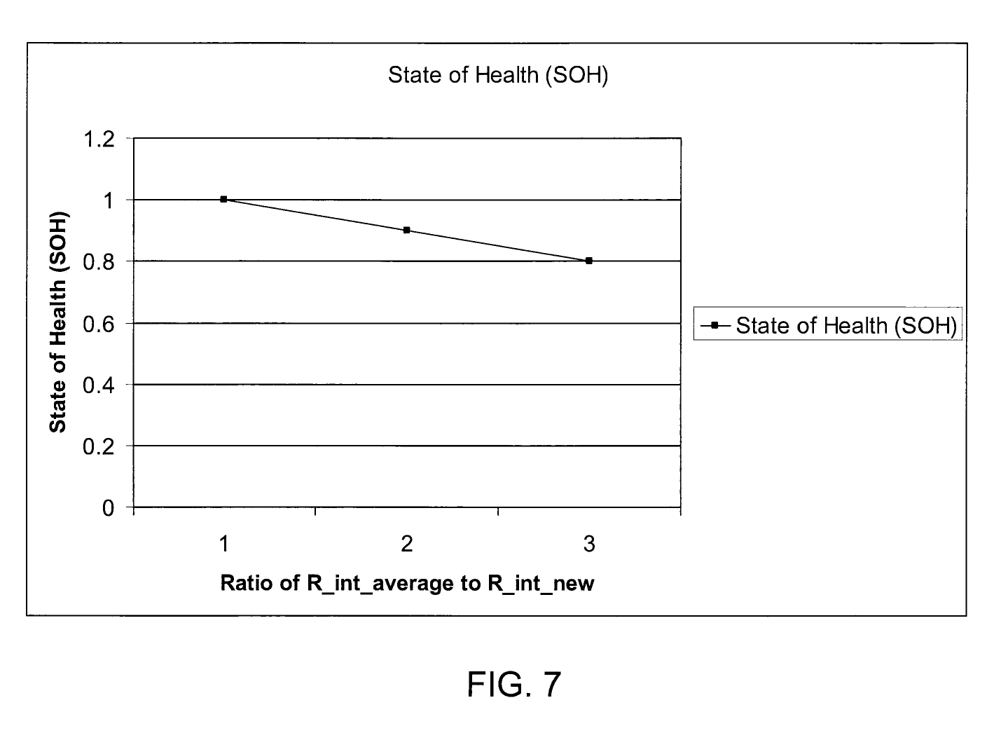

In step 118, the system uses the R_int_average value calculated in step 116 to determine the SOH of the battery or cell. As shown in FIG. 1, this step may be a function of the internal resistance of a new battery or cell (e.g., R_int_new) and R_int_average calculated in step 118. Because the internal resistance of a battery or cell increases as the battery or cell ages, using experimentation it is possible to determine a ratio of R_int_average to R_int_new that indicates that a particular type of battery or cell has degraded. For example, using experimentation it may be determined that a battery has degraded when R_int_average for the battery is three times the value of R_Int_new (i.e., the internal resistance of a new battery) because, at that point, the battery has only 80% of the capacity of a new battery. Accordingly, in one example, the graph illustrated in FIG. 7 may be used to determine a SOH for the battery or cell being tested. FIG. 7 is a graph showing the SOH of a battery or cell for a given ratio of measured internal resistance (R_int_average) to the internal resistance of a new battery or cell. As shown in FIG. 7, when the ratio of R_int_average to R_int_new is 3:1, the battery or cell has a SOH equal to 80% (indicated as 0.8 in FIG. 7) and, at that point, the battery or cell is determined to be in need of replacement. Having calculated the SOH of the battery or cell, it may be displayed in step 120. After displaying the SOH of the battery or cell, the system may be configured to sleep for a pre-determined period of time in step 122.

As shown by the example method 100 of FIG. 1, the present system detects a step change in load current and uses voltage and current measurements made during the step change to calculate the internal resistance of a battery or cell. For example, when the load current is less than 10 A, the system goes to alert mode (e.g., step 108 of FIG. 1). After that, the system looks for a step change in load current to any value between 15 A and 80 A. Whenever the change in load current occurs within a pre-determined time frame (e.g., 0.5 s), the system records the initial and final voltages and currents, and the temperature of the battery or cell. Next, the system calculates the internal resistance of the battery or cell at that moment.

After calculating the internal resistance of the battery or cell, the system may be configured to take into consideration variance in the internal resistance of the battery or cell due to temperature, the state of charge, and the discharge rate. As such, before the internal resistance is compared with that of a new cell, the effect of temperature, SOC and discharge rate may be accounted for by modifying the value of the measured internal resistance of the battery or cell being tested. Accordingly, temperature, SOC and discharge rate compensation may be performed to calculate a present internal resistance of the battery or cell. In some cases, the average of the last 100 internal resistance measurements may be averaged. The final value may then be stored in system memory.

The value of internal resistance for the battery or cell being tested may then be retrieved from memory and compared with the internal resistance of a new battery or cell at standard conditions and the SOH of the battery or cell may be determined. In some applications, when the remaining capacity of the battery or cell is at approximately 80%, it is time to replace the battery or cell.

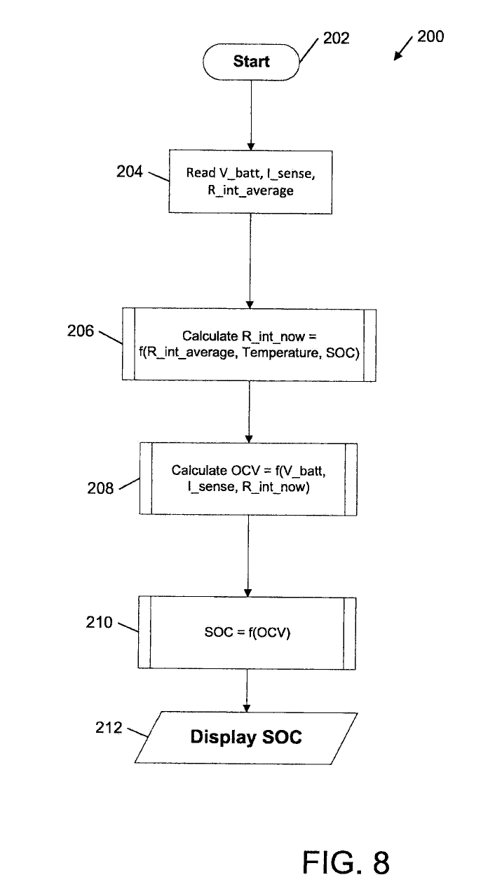

FIG. 8 is a flowchart showing an example method 200 for determining an SOC of a battery or cell. Method 200 starts at step 202 and may be implemented using system 10. In step 204, system 10 measures a battery voltage (V_batt) using a voltage sensor, the bulk discharge current of the battery or cell (I_sense) using a current sensor, and retrieves a value of R_int_average from system memory. R_int_average may be the average of the last 100 internal resistance calculations done using SOH algorithm 100 as illustrated in FIG. 1.

After reading the values of V_batt, I_sense, and R_int_average, the system determines a value of R_int_now in step 206. R_int_now is the value of the internal resistance of the battery or cell at the time step 206 is implemented. Generally, R_int_now is calculated by implementing temperature and SOC compensation on R_int_average, as described above.

After calculating R_int_now, system 10 calculates an open cell voltage (OCV) of the battery or cell in step 208 using the values of V_batt, I_sense, and R_int_now. For example, the OCV of the battery or cell may be equal to the value of V_batt plus I_sense times R_int_now (e.g., OCV=V_batt+I_sense*R_int_now). In this step, the value of I_sense is assigned a positive value for a discharging current, and a negative value for a charging current.

In step 210, the system calculates the SOC of the battery or cell as a function of the OCV of the battery or cell being tested. In one specific implementation, this step includes using a look-up table generated using SOC and OCV measurements performed on a new battery or cell. For example, FIG. 5 is a graph showing a lookup curve for SOC with respect to OCV. The data of the curve may be generated experimentally for a new battery or cell and stored in an accessible data structure within memory of system 10. Using the data, system 10 can, using the OCV determined in step 208, determine the SOC of the battery or cell.

After calculating a value of SOC for the battery or cell, the system may display the value in step 212. This allows a user to verify the SOC of the battery or cell and, depending upon the value, apply appropriate current to charge the battery or cell.

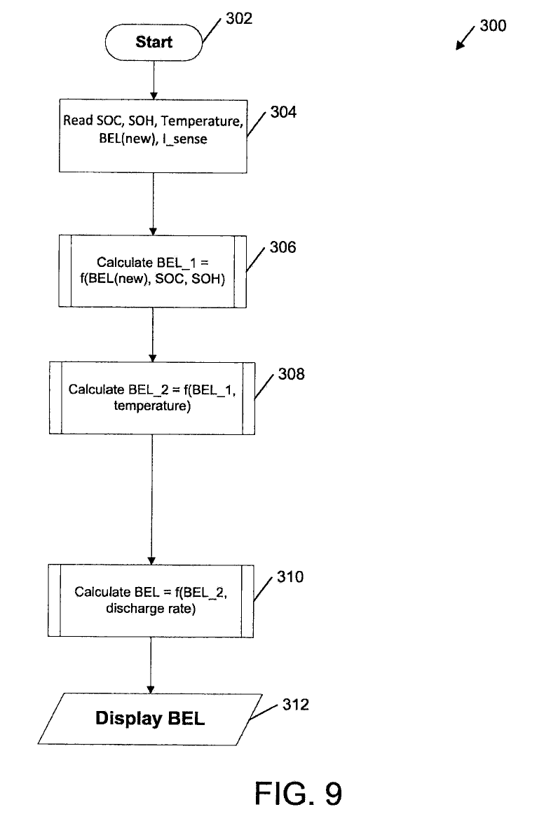

FIG. 9 is a flowchart showing an example method 300 for determining a BEL of a battery or cell. Method 300 starts at step 302 and may be implemented by system 10. In step 304, system 10 reads a SOC, and SOH of the battery or cell being tested using the methods described above. System 10 also measures a temperature of the battery or cell using a temperature sensor and, using a current sensor, measures the bulk discharge current of the battery or cell (I_sense). System 10 also retrieves a value of a pre-determined BEL for a new battery (BEL(new)) from system memory. The BEL of a new battery or cell may be stored in an accessible data structure in the memory of system 10. In the present example, the new battery is of the same configuration as the battery or cell being tested.

In step 306 the system determines a first BEL of the battery or cell (BEL_{—}1). The step may be implemented as a function of BEL(new), and the SOC and SOH of the battery or cell. Generally, BEL_{—}1=BEL(new)*SOH*SOC when SOH and SOC are expressed as number between 0 and 1, as shown in FIGS. 5 and 7 and as described above.

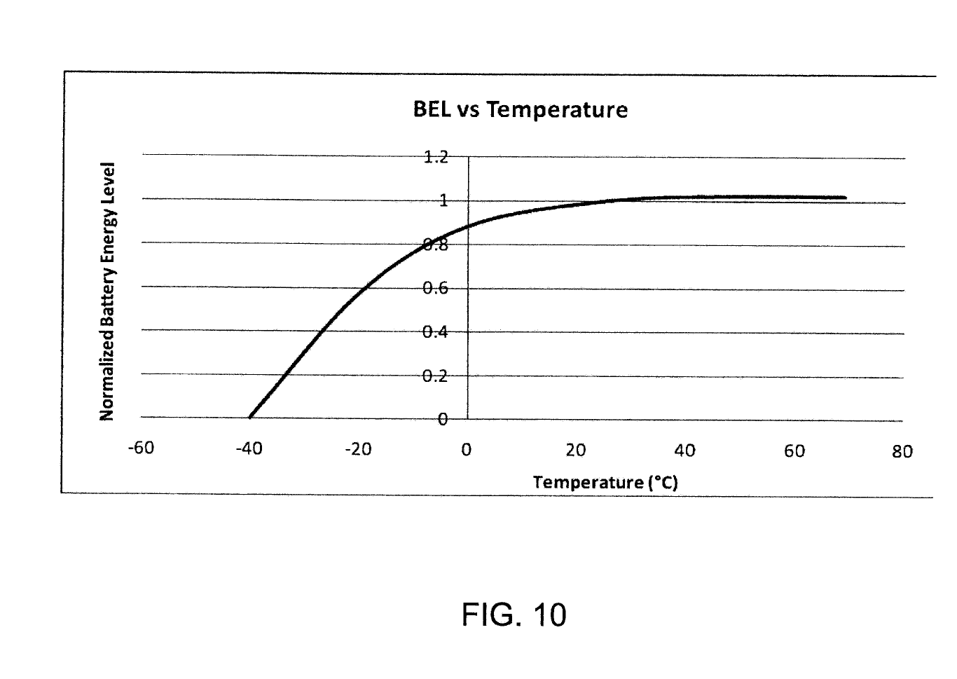

In step 308, system 10 performs temperature compensation on BEL_{—}1 to generate temperature-compensated BEL_{—}2. Generally, BEL_{—}2=BEL_{—}1*t, where t is a temperature compensation coefficient. The temperature compensation coefficient may be determined using experimental data. For example, FIG. 10 is a graph showing a lookup curve for a BEL temperature compensation coefficient with respect to temperature. FIG. 10 shows a normalized BEL value for a given temperature. The curve may be determined experimentally, discretized and stored in an accessible data structure within memory of system 10. Using the lookup curve data, the system can, using the present temperature of the battery or cell, determine an appropriate BEL temperature compensation coefficient. For example, if the present temperature of the battery or cell is 25 degrees Celsius, the BEL temperature compensation coefficient may be set to 1. FIG. 10 illustrates that, as temperature goes down, the BEL for a particular battery or cell decreases. In the specific example of Lithium-polymer batteries or battery cells, the temperature effects may be substantial, with batteries in extremely low-temperature conditions delivering relatively little energy.

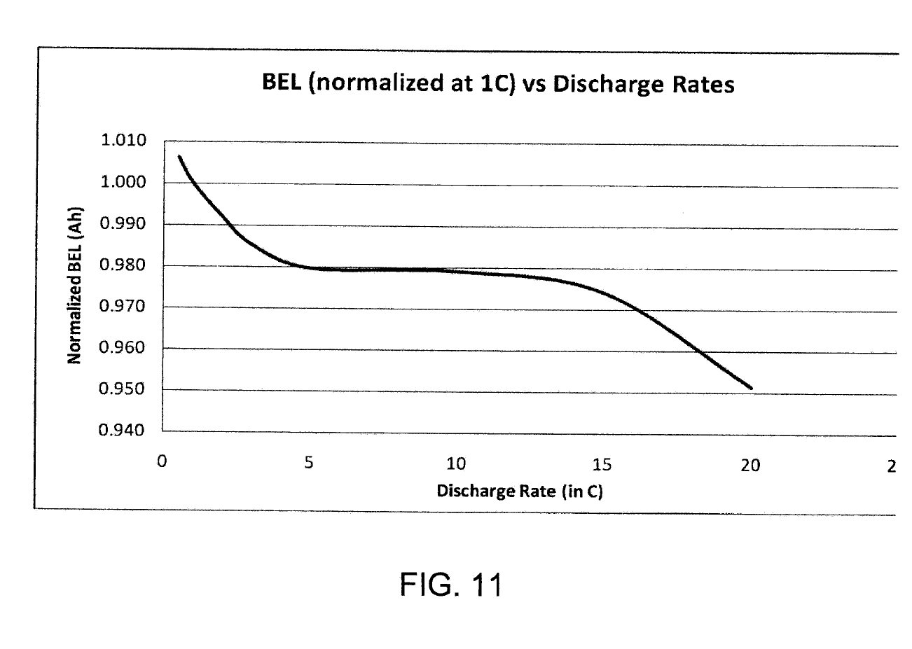

In step 310, the system performs discharge rate compensation on the temperature-compensated value of BEL_{—}2 to generate a value of BEL for the battery or cell being tested. Generally, BEL=BEL_{—}2*d, where d is the discharge rate compensation coefficient. For example, FIG. 11 is a graph showing a lookup curve for a normalized BEL with respect to discharge rate normalized around a value of 1C. The curve may be determined experimentally, discretized and then stored in an accessible data structure within the memory of system 10. Using the lookup curve data, the system can, using the discharge rate of the battery or cell, determine an appropriate BEL multiplier. For example, if the discharge rate of the battery or cell is 1C, the BEL multiplier may be set to 1.

Referring back to FIG. 9, after calculating a value of BEL for the battery or cell, the system may display the value in step 312. This allows a user to verify the BEL of the battery or cell and, depending upon the value, estimate the amount of energy available from the battery at that particular instance of time, which is very important in critical applications.

FIG. 12 is an illustration of some of the functional components in an exemplary implementation of the present system. System 10 includes a battery monitoring system configured to monitor battery or cell 12 and may be configured to implement the disclosed methods. System 10 includes several sensors for capturing data used in monitoring the SOC, SOH and BEL of battery or cell 12 including current sensor 14, temperature sensor 16, and voltage sensor 18. In some implementations of the present system, the sensors are provided by a battery or cell charging system in communication with system 10. Alternatively, system 10 may include the sensors directly. Temperature sensor 16 may be coupled to one of the terminals of battery or cell 12 to measure a temperature of battery or cell 12.

System 10 includes processor 20. Processor 20 collects data from sensors 14, 16, and 18 and is configured to implement the present battery monitoring system and the methods illustrated in FIGS. 1, 8, and 9. Processor 20 may include an MSP430 manufactured by TEXAS INSTRUMENTS, for example. Processor 20 may be coupled to one or more storage devices 24 to store data received from sensors 14, 16, and 18 and any data generated by processor 20 itself. Processor 20 may also be coupled to a user interface 22 for displaying a readout of the SOC, SOH and BEL of battery or cell 12 such as via a computer, LCD screen or other interface for displaying information.

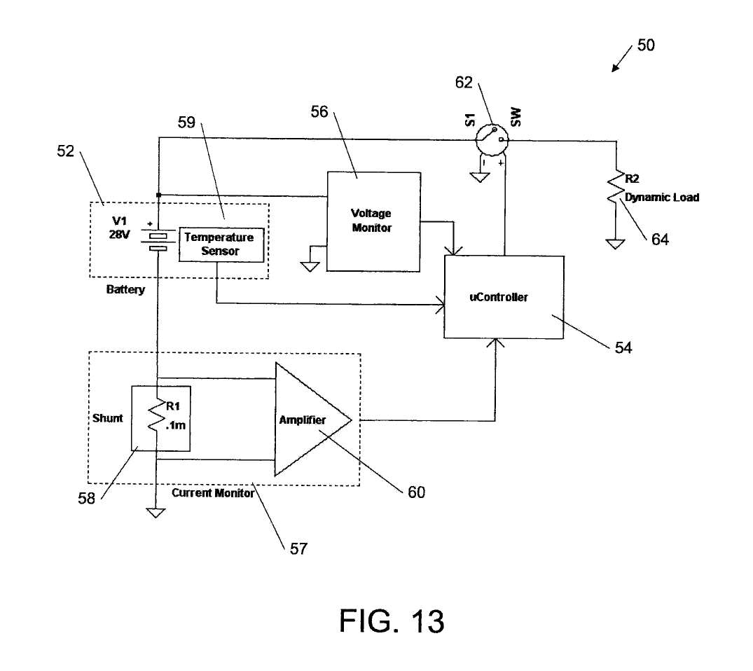

FIG. 13 is a schematic showing an example interconnection of various components of the system illustrated in FIG. 12. As shown in FIG. 13, various components of system 50 are connected to battery or cell 52 to monitor various characteristics of the battery or cell and to implement the present methods. System 50 can measure a terminal voltage, bulk current, and a temperature of battery or cell 52 and supply that information to microcontroller or processor 54 for processing. In this implementation, voltage monitor 56 is connected across the positive terminal of battery or cell 52 and ground. Current monitor 57 may be connected between a negative terminal of battery or cell 52 and ground and includes a low side shunt resistor 58 that is connected to amplifier 60, or it may also be connected on the high side of a battery or cell. The bulk current generated by battery or cell 52 is passed through shunt resistor 58 and amplified by amplifier 60. The amplified value can be used to measure the bulk current of battery or cell 52 and can be detected by microcontroller 54 and used to implement the above methods. System 50 may also include a temperature sensor 59 for measuring a temperature of battery or cell 52, with the temperature sensor being in communication with microcontroller 54 and coupled to one or more terminal of battery or cell 52.

An optional control switch 62 may be integrated into system 50. Finally, battery or cell 52 is connected to load 64. In aeronautical applications, load 64 may include any of the electronic system configuration to be supplied with electrical energy from battery or cell 52.

In certain embodiments of the present system, individual steps recited in FIGS. 1, 8, and 9, may be combined, eliminated, or reordered. In certain embodiments, Applicants' invention includes a battery monitoring system, such as and without limitation system 10 (FIG. 12), wherein the battery monitoring system comprises computer readable program code, such as computer readable program code 21 in communication with processor 20 (FIG. 12), encoded in computer readable medium 23 (FIG. 12), wherein that computer readable program code is executed by a processor, such as processor 20 (FIG. 12), to perform one or more of steps 104, 106, 108, 110, 112, 114, 116, 118, 120, and/or 122, recited in FIG. 1, and/or one or more of steps 204, 206, 208, 210, and/or 212, recited in FIG. 8, and/or one or more of steps 304, 306, 308, 310, and/or 312 recited in FIG. 9.

In certain embodiments, Applicants' invention includes instructions residing in any other computer program product, where those instructions are executed by a computing device external to, or internal to system 50 (FIG. 13), to perform one or more of steps 104, 106, 108, 110, 1120, 114, 116, 118, 120, and/or 122, recited in FIG. 1, and/or one or more of steps 204, 206, 208, 210, and/or 212, recited in FIG. 8, and/or one or more of steps 304, 306, 308, 310, and/or 312 recited in FIG. 9. In either case, the computer readable program code/instructions may be encoded in an information storage medium comprising, for example, a magnetic information storage medium, an optical information storage medium, an electronic information storage medium, and the like. “Electronic storage media” may mean a device such as a PROM, EPROM, EEPROM, Flash PROM, compactflash, smartmedia, and the like.

While one or more embodiments of the present invention have been illustrated in detail, the skilled artisan will appreciate that modifications and adaptations to those embodiments may be made without departing from the scope of the present invention as set forth in the following claims.

What is claimed is:

1. A battery monitoring system, comprising:
a current sensor configured to measure a bulk current of at least one of a battery and a battery cell;
a voltage sensor configured to measure a terminal voltage of the at least one of a battery and a battery cell;
a temperature sensor configured to measure a temperature of the at least one of a battery and a battery cell; and
a processor in communication with each of the current sensor, voltage sensor, and temperature sensor, the processor being configured to:
read a first bulk current of the at least one of a battery and a battery cell at a first time using the current sensor, and,
when the first bulk current is less than a first threshold, read a second bulk current of the at least one of a battery and a battery cell at a second time using the current sensor, and
when the second bulk current has a value between a second threshold and a third threshold and the difference between the first time and the second time is less than a pre-determined delay threshold, use the first and second bulk current values to determine an internal resistance of the battery or cell.

2. The battery monitoring system of claim 1, wherein the processor is configured to:
read a first terminal voltage of the at least one of a battery and a battery cell at the first time using the voltage sensor; and,
when the first bulk current is less than the first threshold, read a second terminal voltage of the at least one of a battery and a battery cell at the second time using the voltage sensor.

3. The battery monitoring system of claim 1, wherein the processor is configured to:
determine a difference between the second bulk current and the first bulk current; and
use the difference to determine a discharge rate compensation factor for the internal resistance of the at least one of a battery and a battery cell.

4. The battery monitoring system of claim 1, wherein the processor is configured to determine a state of health (SOH) of the at least one of a battery and a cell.

5. The battery monitoring system of claim 1, wherein the processor is configured to determine a state of charge (SOC) of the at least one of a battery and a cell.

6. The battery monitoring system of claim 1, wherein the processor is configured to determine a battery energy level (BEL) of the at least one of a battery and a cell.

7. The battery monitoring system of claim 1, wherein the first threshold is a number of amps (A) approximately equal to a value of one-third of a numerical value of an amp-hour capacity of the at least one of a battery and a cell.

8. The battery monitoring system of claim 1, wherein the second threshold is a number of amps (A) approximately equal to a value of one-half a numerical amp-hour capacity of the at least one of a battery and a cell.

9. The battery monitoring system of claim 1, wherein the third threshold is a number of amps (A) approximately equal to a value of three times a numerical amp-hour capacity of the at least one of a battery and a cell.

10. A battery monitoring system, comprising:
a memory for storing data; and
a processor for communicating with each of a current sensor, voltage sensor, and temperature sensor, the processor being configured to:
record load current values and terminal voltage values of at least one of a battery and a cell in the memory,
detect a step change in load current of the at least one of a battery and a cell, the step change beginning at a first time and ending at a second time,
use a first load current value and a first terminal voltage value of the at least one of a battery and a cell detected at the first time, and a second load current value and a second terminal voltage value of the at least one of a battery and a cell detected at the second time to determine an internal resistance of the at least one of a battery and cell.

11. The battery monitoring system of claim 10, wherein the processor is configured to determine whether the difference between the first time and the second time is less than a delay threshold.

12. The battery monitoring system of claim 10, wherein the processor is configured to:
determine a difference between the second load current value and the first load current value; and
use the difference to determine a discharge rate compensation of the internal resistance of the at least one of a battery and a battery cell.

13. The battery monitoring system of claim 10, wherein the processor is configured to determine a state of health (SOH) of the at least one of a battery and a cell.

14. The battery monitoring system of claim 10, wherein the processor is configured to determine a state of charge (SOC) of the at least one of a battery and a cell.

15. The battery monitoring system of claim 10, wherein the processor is configured to determine a battery energy level (BEL) of the at least one of a battery and a cell.

16. A battery monitoring system comprising a processor, a computer readable medium, a current sensor, a temperature sensor, a voltage sensor, and computer readable program code encoded in the computer readable medium to monitor the status of at least one of a battery and a battery cell, the computer readable program code comprising a series of computer readable program steps to effect:
reading a first bulk current of the at least one of a battery and a battery cell at a first time;
when the first bulk current is less than a first threshold, reading a second bulk current of the at least one of a battery and a battery cell at a second time; and
when the second bulk current has a value between a second threshold and a third threshold and the difference between the first time and the second time is less than a delay threshold, using the first and second bulk current values to determine an internal resistance of the battery or cell.

17. The battery monitoring system of claim 16, wherein the computer readable program code includes a series of computer readable program steps to effect:
reading a first terminal voltage of the at least one of a battery and a battery cell at the first time; and,
when the first bulk current is less than a first threshold, reading a second terminal voltage of the at least one of a battery and a battery cell at the second time.

18. The battery monitoring system of claim 16, wherein the computer readable program code includes a series of computer readable program steps to effect:
determining a difference between the second bulk current and the first bulk current; and
using the difference to determine a discharge rate compensation of the internal resistance of the at least one of a battery and a battery cell.

19. The battery monitoring system of claim 16, wherein the first threshold is a number of amps (A) approximately equal to a value of one-third a numerical amp-hour capacity of the at least one of a battery and a cell.

20. The battery monitoring system of claim 16, wherein the second threshold is a number of amps (A) approximately equal to a value of one-half a numerical amp-hour capacity of the at least one of a battery and a cell.

21. The battery monitoring system of claim 16, wherein the third threshold is a number of amps (A) approximately equal to a value of three times a numerical amp-hour capacity of the at least one of a battery and a cell.

22. A battery monitoring system comprising a processor, a computer readable medium, a current sensor, a temperature sensor, a voltage sensor, and computer readable program code encoded in the computer readable medium to monitor the status of at least one of a battery and a battery cell, the computer readable program code comprising a series of computer readable program steps to effect:
recording load current values and terminal voltage values of at least one of a battery or cell in the memory;
detecting a step change in load current of the at least one of a battery and a cell, the step change beginning at a first time and ending at a second time; and
using a first load current value and a first terminal voltage value detected at the first time, and a second load current value and a second terminal voltage value detected at the second time to determine an internal resistance of the at least one of a battery and cell.

23. The battery monitoring system of claim 22, wherein the computer readable program code includes a series of computer readable program steps to effect determining whether the difference between the first time and the second time is less than a delay threshold.

24. The battery monitoring system of claim 22, wherein the computer readable program code includes a series of computer readable program steps to effect:
determining a difference between the second load current value and the first load current value; and
using the difference to determine a discharge rate compensation of the internal resistance of the at least one of a battery and a battery cell.
